(19) United States
(12) Patent Application Publication
(10) Pub. No.: US 2022/0121084 A1
(43) Pub. Date: Apr. 21, 2022

(54) MONOLITHICALLY INTEGRATED LASER-NONLINEAR PHOTONIC DEVICES

(71) Applicant: THE REGENTS OF THE UNIVERSITY OF CALIFORNIA, Oakland, CA (US)

(72) Inventors: John E. Bowers, Santa Barbara, CA (US); Lin Chang, Goleta, CA (US)

(21) Appl. No.: 17/492,381

(22) Filed: Oct. 1, 2021

Related U.S. Application Data
(60) Provisional application No. 63/086,156, filed on Oct. 1, 2020.

(51) Int. Cl. G02F 1/35; G02F 1/365; H01S 5/12; H01S 5/026

(52) U.S. Cl. CPC G02F 1/3503; G02F 1/365; G02F 2203/56; H01S 5/026; H01S 5/12

(57) ABSTRACT

An integrated laser/non-linear device includes a semiconductor/dielectric substrate, a nonlinear device fabricated on the semiconductor/dielectric substrate and a pump laser fabricated on the same semiconductor/dielectric substrate.

### STATEMENT OF GOVERNMENT INTEREST

This invention was made with Government support under Grant (or Contract) No. HR0011-15-C-0055, awarded by the Department of Defense Advanced Research Projects Agency (DARPA). The Government has certain rights in this invention

### BACKGROUND

Non-linear photonic devices are utilized to fabricate devices such as frequency comb (microcomb) generators, which are optical devices capable of generating very sharp and equidistant frequency lines in response to an input frequency. Frequency combs are useful in a number of applications, including optical communications, conversion from optical frequency ranges to RF/Microwave frequency ranges, light detection and ranging (LIDAR), spectroscopy, and timekeeping.

Typically, a laser fabricated on a first chip is connected via fiber or chip-to-chip coupling to the non-linear photonic device (i.e., frequency comb generator) to generate the desired output frequencies in response to the input provided by the laser. This increases the size, cost and power consumption of the non-linear photonic device.

It would be beneficial to integrate lasers and non-linear photonic devices on a simple integrated circuit. However, non-linear materials most commonly utilized are dielectrics, which provide low nonlinear optical coefficients and therefore require strict requirements on the quality factors of the cavities in order to operate efficiently. These requirements increase the cost of fabrication of the non-linear photonic devices. In addition, the dielectric material utilized for non-linear photonic devices are not easily integrated with active components (e.g., lasers) due to incompatibilities between design and fabrication of semiconductor materials and dielectric materials.

Utilization of photonic integration to assemble laser and nonlinear device on a same chip would therefore be beneficial, which can make the whole system low cost and scalable.

### SUMMARY OF THE INVENTION

According to one aspect, an integrated laser/non-linear device includes a semiconductor/dielectric substrate, a nonlinear device fabricated on the semiconductor/dielectric substrate, and a pump laser fabricated on the same semiconductor/dielectric substrate.

According to another aspect, an integrated non-linear laser includes a waveguide and a resonator laser coupled to the waveguide via a directional coupler, wherein at least a portion of the resonator laser includes a gain section and at least a portion of the resonator laser comprises a non-linear waveguide.

According to another aspect, a frequency comb generator includes a resonator laser, a nonlinear resonator ring, and a waveguide. In some embodiments, the nonlinear resonator ring is coupled to the resonator laser to receive an input optical signal at a first frequency or first plurality of frequencies and to generate in response a frequency comb output. The waveguide is coupled via a coupler to the nonlinear resonator to receive the frequency comb optical output in response to the first frequency of first plurality of frequencies of the input optical signal.

According to another aspect, A frequency comb generator includes a gain waveguide, a no-linear resonator, and a waveguide. The non-linear resonator is coupled to the gain waveguide to receive an input optical signal at a first frequency or first plurality of frequencies and to generate in response a frequency comb output. The waveguide coupled via a coupler to the non-linear resonator to receive the frequency comb optical output in response to the first frequency of first plurality of frequencies of the input optical signal.

### DESCRIPTION OF THE DRAWINGS

FIG. 1a is a cross-sectional view of a non-linear waveguide according to some embodiments; FIG. 1b is a cross-sectional view of a simulated intensity distribution of the waveguide fundamental transverse electric (TE) mode for comb generation according to some embodiments; FIG. 1c is a simulated group-velocity dispersion (GVD) of a nonlinear waveguide having different widths according to some embodiments.

FIG. 2a is a scanning electron microscope (SEM) top view of a SiO₂ hard mask with and without reflow applied after the lithography process; FIG. 2b is a SEM view of the sidewall of the nonlinear waveguide; FIG. 2c is a SEM cross-sectional view of nonlinear waveguide after passivation and deposition of a thin layer of SiO₂; FIG. 2d is a SEM perspective view of a ring resonator.

FIG. 3a is a graph illustrating measured relative mode frequencies Dᵢₙₜ plotted verse relative mode number μ according to some embodiments; FIG. 3b is a graph illustrating measured transmission spectrum of a resonance around 1518 nm according to some embodiments; and FIG. 3c is a graph illustrating resonance with splits due to backscattering according to some embodiments.

FIG. 4a is a graph illustrating the frequency comb spectrum generated in response to a 1 THz resonator at a pump power of 36 μW according to some embodiments; FIG. 4b is a graph illustrating the frequency comb spectrum generated in response to a 1 THz resonator at a pump power of 300 μW according to some embodiments; FIG. 4c is a graph illustrating the frequency comb spectrum generated in response to a 450 THz resonator at a pump power of 250 μW according to some embodiments.

FIG. 5a is a top view of a monolithically integrated laser and microresonator comb generator according to some embodiments; FIG. 5b is a top view of a monolithically integrated laser and supercontinuum waveguide comb generator according to some embodiments.

FIG. 6a is a top view of an integrated nonlinear laser utilizing an integrated gain section according to some embodiments; FIG. 6b is a top view of an integrated nonlinear laser utilizing a hybrid nonlinear waveguide having gain according to some embodiments.

FIG. 7a is a top view of a frequency comb generator utilizing a laterally coupled ring laser and nonlinear resonator according to some embodiments; FIG. 7b is a perspective view of a frequency comb generator utilizing vertically coupled ring laser and nonlinear resonator according to some embodiments; FIG. 7c is a top view of a frequency comb generator utilizing a nonlinear resonator coupled with a gain waveguide section according to some embodiments.

FIG. 8a is a top view of the chip-scale laser frequency comb; FIG. 8b is a cross-sectional view of the chip-scale laser frequency comb, and FIG. 8c is a graph illustrating microcomb generation with sweeping laser current Iₗₐₛₑᵣ and varying phase tuner current Iₚₕₐₛₑ to control the optical phase of self-injection locking according to some embodiments.

### DETAILED DESCRIPTION

According to some embodiments, the present disclosure describes utilization of a semiconductor/dielectric substrate to fabricate non-linear devices having an intrinsic quality factor Q equal to or greater than 1.5×. For example, in some embodiments, Aluminum-Gallium-Arsenide on insulator (AlGaAsOI) may be utilized as the nonlinear material. The high-quality factor Q, high Kerr nonlinear coefficients, and compact mode volume allow for ultra-efficient frequency comb generation. For example, in one embodiment frequency comb generation was initiated at approximately 36 micro-watts (μW). In addition, fabrication of nonlinear devices based on semiconductor material is much simpler as compared with typical high Q non-linear platforms using dielectric material. For example, based on the utilization of AlGaAsOI as the non-linear material, ultra-efficient monolithically integrated laser and frequency comb generators can be fabricated, as well as hybrid nonlinear waveguides with integrated gain sections. In other embodiments, dielectric materials (included silicon nitride, silica, Ta₂O₅, LiNbO₃, diamond, Hydex, MgF₂) may be utilized to fabricate nonlinear devices, wherein the heterogeneous bonding of the dielectric substrate with the semiconductor substrate utilized to fabricate the active device (e.g., laser) to provide a monolithically integrated laser-nonlinear photonic device, substrates may be utilized.

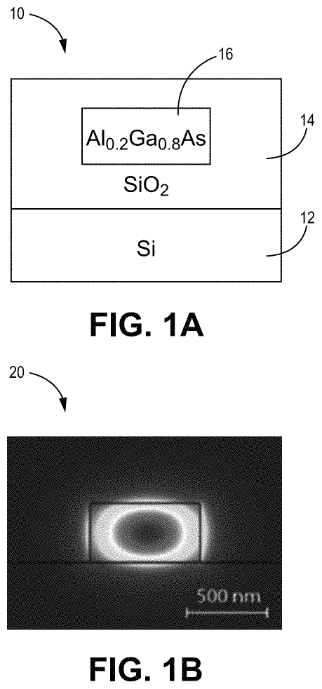

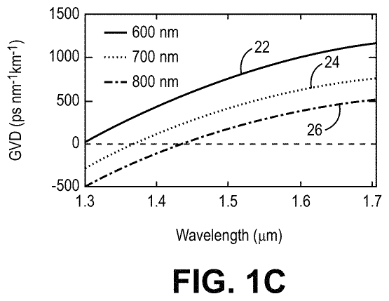

FIG. 1a is a cross-sectional view of a semiconductor based non-linear waveguide according to some embodiments. A Silicon Dioxide (SiO₂) insulating layer 14 is formed on a silicon substrate (Si) 12. The nonlinear waveguide 16 is formed within the SiO₂ insulating layer 14. In some embodiments, the nonlinear waveguide 16 comprises Aluminum-Gallium-Arsenide (AlGaAs) and is referred to as AlGaAsOI because it is fabricated on an insulating layer. 14. In other embodiments, the nonlinear waveguide 16 may be fabricated using a dielectric nonlinear material.

As discussed in more detail below, the nonlinear waveguide is fabricated as part of a nonlinear device (e.g., microresonator, supercontinuum waveguide) that receives an optical input at a first frequency or first plurality of frequencies and generates in response a plurality of comb frequencies related to the input frequency. It is desirable that the nonlinear waveguide 16 be highly nonlinear while also being optically efficient. In some embodiments, this is achieved by utilizing a material having a high nonlinear coefficient, high index contrast, and high quality factors. In particular, in some embodiments, the nonlinear waveguide is fabricated from a semiconductor material, such as GaAs, GaN, InSb, InAs, InₓGa₁₋ₓN, AlₓGa₁₋ₓAs, InₓGa₁₋ₓAs_{1-y}P_{1-y}, InₓGa₁₋ₓAs_{1-y}Sb_{1-y}, InₓGa₁₋ₓSb_{1-y}P_{1-y}, InₓGa_{y}Al_{1-x-y}As, InₓGa_{y}Al_{1-x-y}N where 0<x<1, 0<y<1 formed within an insulating SiO₂ layer on a semiconductor substrate (e.g., silicon substrate). For example, in some embodiments the waveguide is an AlGaAsOI waveguides allows the generation of devices such as ultra-efficient frequency comb generators. In other embodiments, the nonlinear waveguide is fabricated from a dielectric material, such as silicon nitride, silica, Ta₂O₅, LiNbO₃, diamond, Hydex, and MgF₂. In some embodiments, the dielectric waveguide is fabricated on a dielectric substrate and heterogeneously integrated via wafer bonding to the semiconductor substrate utilized to fabricate the active device (e.g., laser).

For example, AlGaAs provides a very high nonlinear optical coefficient, which makes it a very attractive nonlinear optical material for use in nonlinear devices such as frequency comb generators. Table 1 provides a list of linear and nonlinear optical properties of various materials suitable for chip-based nonlinear photonics, wherein linear optical properties are described by the refractive index and nonlinear optical properties are described by the Kerr nonlinear coefficient (η₂) (m² W⁻¹).

TABLE 1

| Material | Refractive index | n₂ (m²W⁻¹) |
|---|---|---|
| Silica | 1.45 | 3 × 10⁻²⁰ |
| α-Si−H | 3.73 | 1.7 × 10⁻¹⁷ |
| Si₃N₄ | 2 | 2.5 × 10⁻¹⁹ |
| LiNbO₃ | 2.21 | 1.8 × 10⁻¹⁹ |
| Ta₂O₅ | 2.1 | 7.23 × 10⁻¹⁹ |
| Hydex | 1.7 | 1.15 × 10⁻¹⁹ |
| Si | 3.47 | 5 × 10⁻¹⁸ |
| GaN | 2.31 | 7.8 × 10⁻¹⁹ |
| GaP | 3.05 | 6 × 10⁻¹⁸ |
| Diamond | 2.38 | 8 × 10⁻²⁰ |
| AlN | 2.12 | 2.3 × 10⁻¹⁹ |
| (Al)GaAs | 3.3 | 2.6 × 10⁻¹⁷ |
| SiGe | 3.59 | 2.7 × 10⁻¹⁸ |
| Ge | 4.33 | 4.4 × 10⁻¹⁷ |
| As₂S₃ | 2.43 | 3.8 × 10⁻¹⁸ |
| As₂Se₃ | 2.81 | 2.4 × 10⁻¹⁷ |

As shown in Table 1, (Al)GasAs provides a Kerr nonlinear coefficient of approximately 2.6×10⁻¹⁷, which is approximately two orders of magnitude higher than that of Si₃N₄ (η₂=2.5×10⁻¹⁹) one hundred times greater than Si₃N₄ (η₂=2.3×10⁻¹⁹).

Another benefit of AlGaAs is the relatively large bandgap of the material as compared to other commonly used semiconductor materials, such as Silicon (Si) (1.1 eV) or Indium-Phosphide (InP) (1.34 eV). In some embodiments, the nonlinear material is comprised of AlₓGa₁₋ₓAs, wherein the ratio of Aluminum to Gallium can be modified to vary the bandgap of waveguide from 1.42 eV (872 nm) to 2.16 eV (574 nm). The bandgap associated with AlGaAs avoids two photon absorption (TPA) at the two most important telecom band (1310 nm and 1550 nm). In one embodiment, the value of x AlₓGa₁₋ₓAs is selected to be 0.2 (Al_{0.2}Ga_{0.8}As) in order to generate a frequency comb at C-band wavelengths. In some embodiment, higher Al levels (e.g., greater than 0.2) may be utilized when targeting shorter pump wavelengths.

In addition, AlGaAs provides for intrinsic quality factor Q of approximately 1.5×10⁶. In general, the quality factor of a given cavity/waveguide describes the loss resulting from interaction of the optical signal with the walls, the loss associated with the dielectric material filling the cavity, and losses associated with undisclosed holes in the cavity geometry. In some embodiments, the nonlinear waveguide 16 is fully etched with sub-micron dimensions, which provides anomalous group velocity dispersion (GVD) at the wavelength of the input frequency (e.g., pump wavelength). For example, telecommunications systems typically operate in the 0 band and the C band. In some embodiments, the AlGaAsOI nonlinear waveguide 16 provides strong material dispersion compensated by the waveguide geometry. In some embodiments, the thickness of the AlGaAs nonlinear waveguide 16 is set to be approximately 400 nm, at which the calculated GVD is anomalous at C band wavelength for waveguides with several different widths (e.g., 600 nm illustrated by line 22, 700 nm illustrated by line 24, and 800 nm illustrated by line 26) as shown in FIG. 1c. Compared to commonly used Si₃N₄ waveguides utilized in typical comb generation, the AlGaAs nonlinear waveguide reduces the mode volume by a factor of about 4. A benefit of reducing the mode volume enhances the photon intensity and enables more compact designs.

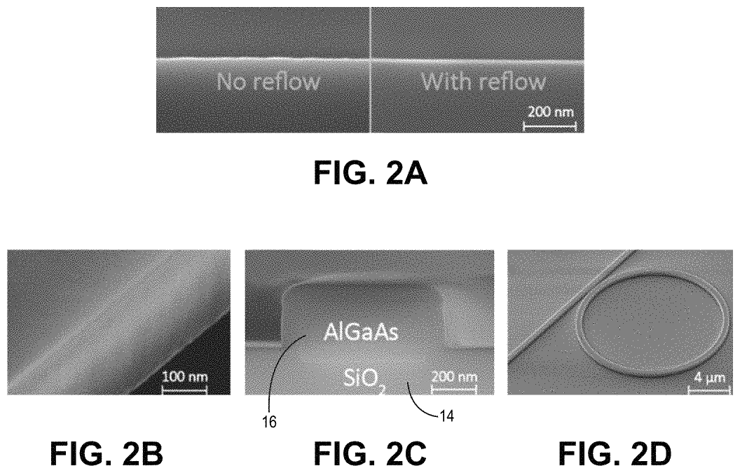

In addition to the dimensions of the nonlinear waveguide 16, reducing sidewall roughness reduces the propagation loss associated with the nonlinear waveguide 16. In particular, because the mode size of the waveguide is small there is significant interaction of the mode with the waveguide sidewall. In addition, the strong index contrast between the nonlinear AlGaAs and the SiO₂ cases an increase in the scattering loss. Reducing the sidewall roughness during fabrication will therefore reduce the propagation losses within the waveguide. In some embodiments, the patterned photoresist is reflowed after the lithography process. For example, FIG. 2a is a scanning electron microscrope (SEM) top view of the patterned SiO₂ hard mask both without (left) and with (right) reflow of the photoresist, both of which are exposed using an ASML 248 nm DUV stepper. As shown in the image on the left, significant roughness is provided at the edge of the SiO₂ hard mask, which would be transferred to the sidewall of the nonlinear waveguide 16 after AlGaAs etch. Applying a reflow step after the lithography process associated with the SiO₂ hard mask, the resist boundary is smoothed out and the roughness is hardly visible in the image on the right of FIG. 2a. In some embodiments, the change in resist shape cased by reflow can be pre-calibrated and taken into account in mask design, which enables a dimension control of the waveguide width on a nanometer scale.

In addition to utilizing a reflow of the photoresist after the lithography process, in some embodiments scattering loss (sidewall roughness) is further reduced utilizing an optimized dry etch process. In some embodiments, an inductively coupled plasma (ICP) etch is utilized for both the hard mask and the AlGaAs. In particular, in some embodiments CHF₃/CF₄/N₂ gases are utilized for etching the SiO₂ and Cl₂/N₂ is utilized for etching the AlGaAs. For example, as shown in FIG. 2b, a perspective SEM view of the nonlinear waveguide 16 is shown that illustrates the smooth etching profile of the nonlinear waveguide. In addition, FIG. 2c is a SEM cross-sectional view of the nonlinear waveguide 16 after passivation and deposition of a thin layer of SiO₂. As shown in FIG. 2c, the sidewall angle of the nonlinear waveguide 16 is approximately 90 degrees. FIG. 2d is a perspective view illustrating fabrication of a ring resonator based on the nonlinear waveguide 16.

In some embodiments, a surface passivation treatment is applied to the waveguide surface to reduce absorption caused by defect states at the surface of the materials. For example, in some embodiments a 5 nm thick Al₂O₃ layer is deposited utilized an atomic layer deposition (ALD) technique, which surrounds the nonlinear waveguide 16 and passivates the AlGaAs surface. In other embodiments, other methods may be utilized to reduce surface dissipation such as wet nitridation.

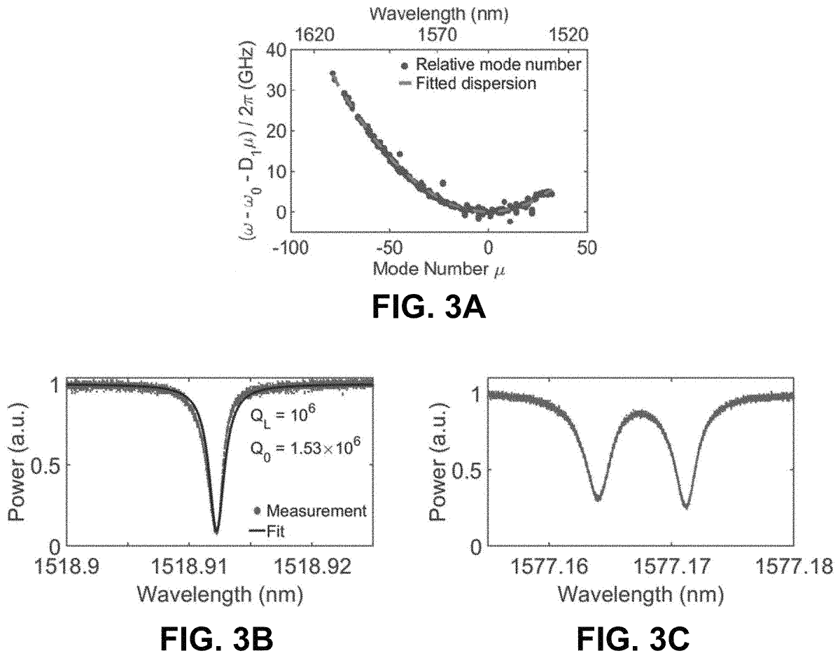

FIG. 3a is a graph illustrating measured relative mode frequencies Dᵢₙₜ plotted verse relative mode number μ for an experimental nonlinear resonator according to some embodiments; FIG. 3b is a graph illustrating measured transmission spectrum of a resonance around 1518 nm according to some embodiments; and FIG. 3c is a graph illustrating resonance with splits due to backscattering according to some embodiments.

As discussed above, the dispersion of the waveguide plays a critical role. To characterize the GVD of the waveguides a ring resonator was fabricated having a 100 μm radius and a free spectral range (FSR) of 118 GHz. The resonance frequency of a mode family was measured as a function of relative mode number μ, relative to a reference resonance at wo, which is around 1550 nm. The resonance frequency ω_{μ} of the modes can be expended in Taylor series as:

ω_{μ}=ω₀+μD₁+½μ²D₂+⅙μ³D₃+. . . (1)

where D₁/2π refers to the FSR around ω₀ and D₂ is related to the GVD β₂ by

$${D}_{2} = - \frac{c}{n} {D}_{1}^{2} {β}_{2} .$$

FIG. 3a shows the measured relative mode frequencies Dᵢₙₜ≡ω_{μ}−ω₀−μD₁. By fitting the data, second order dispersion D₂/2π is extracted to be 10.8 MHz. This confirms that the resonator is operated in the anomalous dispersion regime.

FIG. 3b is a graph lustrating the estimated quality factor of an experimental resonator based on the transmission spectrum of the resonances according to some embodiments. As shown in FIG. 3b, a 1 THz ring resonator having a waveguide width of 700 nm and a radius of 12 μm has a resonance at a wavelength of ˜1519 nm. The intrinsic qualify factor is extracted to be ˜1.53×10⁶, which correspond to a propagation less around 0.4 dB/cm.

Considering the compact mode size (˜0.28 μm²) and small radius of the ring, it is reasonable to believe that this platform has waveguide loses that are comparable to the state of the art fully etched silicon on insulator (SOI) or even many commonly used dielectric waveguides.

FIG. 3c presents the transmission spectrum of a resonance, which shows a split of the mode. A split mode is usually observed in high-Q resonators sensitive to small imperfections or scatters at waveguide surfaces. This indicates that the quality factors Q are still limited by the scattering loss and can be further reduced by optimizing the fabrication process.

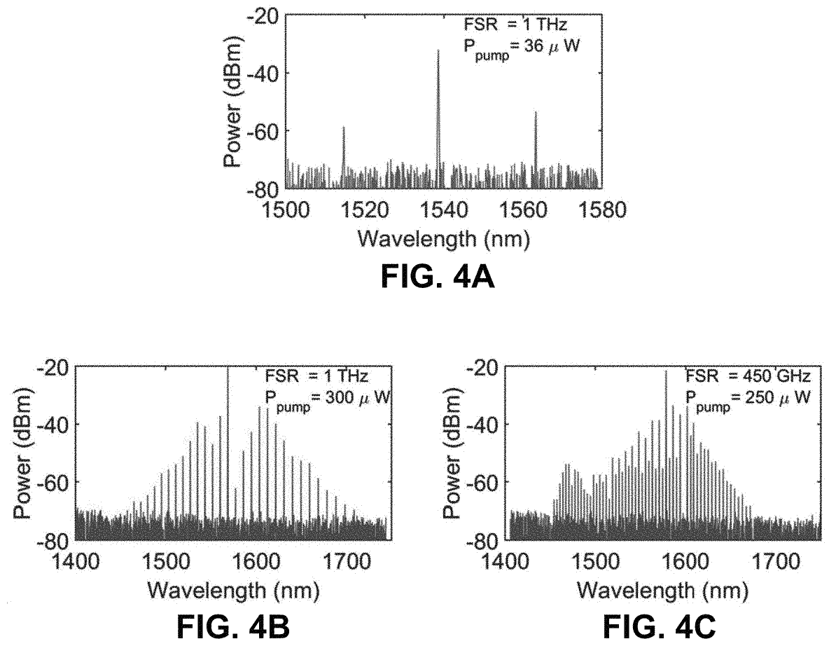

FIG. 4a is a graph illustrating the frequency comb spectrum generated in response to a 1 THz resonator at a pump power of 36 μW according to some embodiments; FIG. 4b is a graph illustrating the frequency comb spectrum generated in response to a 1 THz resonator at a pump power of 300 μW according to some embodiments; FIG. 4c is a graph illustrating the frequency comb spectrum generated in response to a 450 THz resonator at a pump power of 250 μW according to some embodiments

In particular, FIG. 4a illustrates the frequency comb spectrum generated by a 1 THz resonator under pump power of approximately 36 μW. As shown in FIG. 4a, the onset of frequency comb generation is initiated with the generation of two frequencies in response to the input frequency at approximately 1540 nm. This demonstrates the ability to generate efficient Kerr comb by pumping the resonators at C-band wavelengths.

FIG. 4b illustrates the frequency comb spectrum resulting from an increase in power from 36 μW to 300 μW. As illustrated, significant increase in comb frequencies is provided as a result in the increase in pump power. In particular, the generated frequency comb lines cover a >250 nm wide spectral range under a power of only 300 μW.

FIG. 4c illustrates the frequency comb spectrum generated in response to a 450 GHz resonator at a pump power of 250 μW. In the example shown in FIG. 4c, the frequency comb generated covers a span of over 200 nm with more than 50 comb lines. Further analysis indicates that under 1×10⁶ quality factor, only ˜2 mW pump power should be sufficient to generate octave span THz comb with double dispersive wave if proper dispersion engineering is applied, which is essential for f-2f self-referencing and frequency synthesis applications.

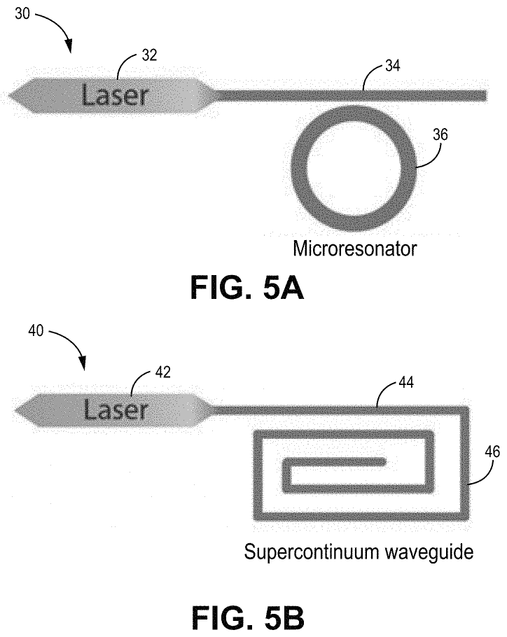

Referring now to FIGS. 5a and 5b, top views of a monolithically integrated laser and frequency comb generator are provided. In particular, the embodiment shown in FIG. 5a utilizes a microresonator to implement the frequency comb generator while FIG. 5b utilizes a supercontinuum waveguide to implement the frequency comb generator.

In the embodiment shown in FIG. 5a, the monolithically integrated device 30 includes a pump laser 32, optical waveguide 34 and microresonator 36. In some embodiments, the pump laser provides an optical output at a first frequency or first plurality of frequencies. Optical waveguide 34 is coupled to the laser 32 and communicates the optical output to the microresonator 36. Microresonator 36 is coupled to the optical waveguide 34 to receive the optical output provided by the laser at a first frequency of first plurality of frequencies. The microresonator 36 is constructed utilizes nonlinear materials, such as those described with respect to FIGS. 1a-1c. In particular, in some embodiments the nonlinear waveguide utilized to construct microresonator 36 is comprised of nonlinear semiconductor material and/or nonlinear dielectric material. Similarly, in the embodiment shown in FIG. 5b the monolithically integrated device 40 includes a laser 42, a waveguide 44, and a supercontinuum waveguide 46. In this embodiment, the laser 42 is a mode-locked laser that generates a frequency comb having a relatively narrow spectrum. The supercontinuum waveguide 46 is configured to broaden the relatively narrow spectrum of the frequency comb provided by the mode-locked laser 42. The microresonator 36 and/or supercontinuum waveguide 46 may be constructed utilizing nonlinear materials, including for example nonlinear semiconductor materials such as GaAs, GaN, InSb, InAs, InₓGa₁₋ₓN, AlₓGa₁₋ₓAs, InₓGa₁₋ₓAs_{1-y}P_{1-y}, InₓGa₁₋ₓAs_{1-y}Sb_{1-y}, InₓGa₁₋ₓSb_{1-y}P_{1-y}, InₓGa_{y}Al_{1-x-y}As, InₓGa_{y}Al_{1-x-y}N where 0<x<1, 0<y<1 and/or nonlinear dielectric materials such as silicon nitride, silica, Ta₂O₅, LiNbO₃, diamond Hydex, and MgF₂.

With respect to FIGS. 5a and 5b, the components are fabricated on the same integrated circuit or chip. For example, the pump laser 32 (or 42) may be fabricated based on commonly utilized semiconductor materials (e.g., Si, GaAs, InP) whose gain medium can be either quantum wells (QWs), quantum dots (QDs), or other types of active medium capable of lasing. For example, in some embodiments pump laser 32 (or 42) utilizes one or more of Fabry-Perot (FP) laser, distributed feedback laser (DFB), Distributed Bragg reflector (DBR) laser, external cavity laser, mode lock laser, reflective semiconductor optical amplifier (RSOA), and/or other types of well-known devices. In some embodiments, fabrication of the pump laser 32 (or 42) on the device with the microresonator 36 or supercontinuum waveguide 46 utilizes epitaxial growth techniques. In other embodiments, the nonlinear device (e.g., microresonator 36 or supercontinuum waveguide 46) is fabricated on a first wafer and the active device (e.g., pump laser 32) is fabricated on a second wafer, wherein the wafers are heterogeneously integrated with one another via wafer bonding techniques.

With respect to the embodiment shown in FIG. 5a, frequency comb generation may be initiated at extremely low power consumption levels. For example, in one embodiment Kerr frequency comb generation threshold was initiated at a input power of ˜36 μW based on a microresonator having a 1 THz free spectral range (FSR). As discussed above, this is a result of the combination of quality factors, high nonlinear coefficient, and small mode volume associated with the microresonator and/or supercontinuum waveguide.

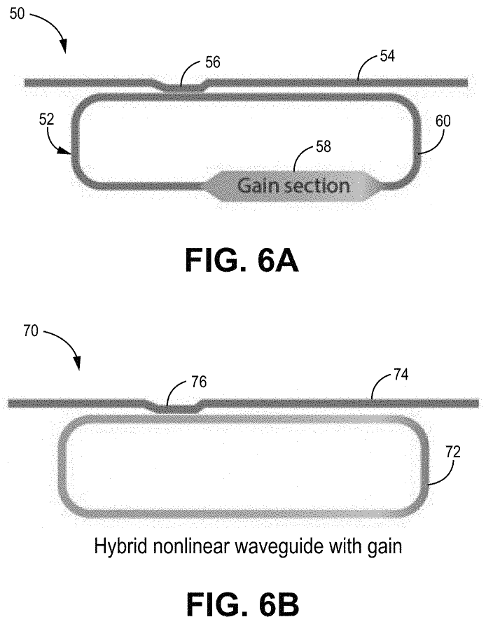

Referring now to FIGS. 6a and 6b, examples of integrated comb lasers are illustrated. In particular, FIG. 6a illustrates an integrated comb laser 50 that includes waveguide 54, coupler 56, and ring resonator 52, which includes nonlinear waveguide 60 and gain region 58. The device is referred to as an integrated comb laser because it provides gain material capable of providing being pumped to provide the optical input to the comb generator. That is, in some embodiments gain section 58 is utilized to generate the optical input provided to the ring resonator without requiring coupling of an external laser to the ring resonator. In other embodiments, however, an external laser may be provided in addition to the gain region 58 to provide the requisite optical input necessary to initiate the frequency comb. In other embodiments, pumping of the gain section 58 is sufficient to provide the requisite power to initiate the frequency comb. In some embodiments, the gain region is fabricated utilizing quantum wells (QWs) and/or quantum dots (QDs) (e.g., (Al)InGaAs QWs and/or InAs QDs).

With respect to the nonlinear waveguide 60, in some embodiments the waveguide is fabricated utilizing a nonlinear semiconductor material and/or nonlinear dielectric material. As described above, nonlinear semiconductor material includes materials such as GaAs, GaN, InSb, InAs, InₓGa₁₋ₓN, AlₓGa₁₋ₓAs, InₓGa₁₋ₓAs_{1-y}P_{1-y}, InₓGa₁₋ₓAs_{1-y}Sb_{1-y}, InₓGa₁₋ₓSb_{1-y}P_{1-y}, InₓGa_{y}Al_{1-x-y}As, InₓGa_{y}Al_{1-x-y}N where 0<x<1, 0<y<1. Nonlinear dielectric materials may include silicon nitride, silica, Ta₂O₅, LiNbO₃, diamond Hydex, and MgF₂.

In some embodiments, nonlinear materials such as AlGaAs provides relatively high gain. For example, the gain region 58 provides gain (i.e., lasing) while the nonlinear waveguide 60 provides the nonlinearity and dispersion required to generate the frequency comb. In some embodiments, the integrated comb laser 50 is capable of generating a frequency comb in the O frequency band, the C frequency band, and/or both the O and C frequency bands. The frequency comb output is coupled to the waveguide 54 via coupler 56.

In contrast, FIG. 6b illustrates a hybrid nonlinear waveguide 70, which includes waveguide 74, coupler 76, and ring resonator with gain 72. In this embodiment, rather than add a longer wavelength gain section to the nonlinear ring resonator as shown in FIG. 6a, the ring resonator with gain 72 adds the gain medium directly into the nonlinear waveguide. As such, the nonlinear waveguide 72 may be directly pumped to obtain gain and contribute to the nonlinear process at the same time. In some embodiments, quantum well (QW) and/or quantum dot (QD) intermix and/or regrowth is utilized to provide vertical current injection pumping of the ring resonator with gain 72. In some embodiments, the quantum wells (QWs) and/or quantum dots (QDs) are fabricated utilizing (Al)InGaAs and/or InAs, and the nonlinear waveguides are once again fabricated utilizing AlGaAs.

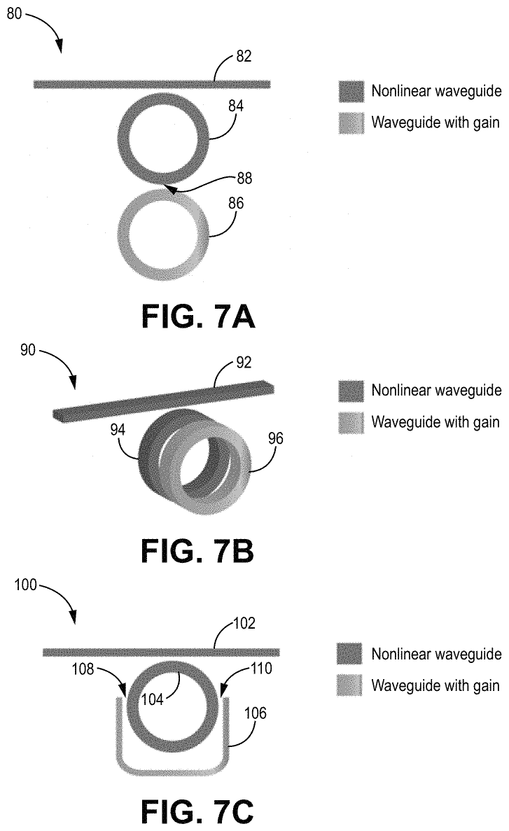

Referring to FIGS. 7a-7c, embodiments are illustrated that rely on coupling two or three (or more) sets of coupled resonators. As described in more detail below, in each embodiment one of the resonators is utilized as the laser cavity and at least one of the other resonators is a nonlinear resonator coupled receive the first frequency or first plurality (e.g., comb) of frequencies generated by the laser cavity.

FIG. 7a is a top view illustrating the layout of a comb generator 80, which includes a waveguide 82, nonlinear ring resonator 84, and laser cavity ring resonator 86. In this embodiment, the nonlinear ring resonator 84 is located adjacent to laser cavity ring resonator 86. In some embodiments, the laser cavity ring resonator 86 is fabricated utilizing quantum wells (QWs) and/or quantum dots (QDs) (e.g., (Al)InGaAs QWs and/or InAs QDs), which generates an optical signal at a first frequency or first plurality of frequencies. The optical signal generated by the laser cavity ring resonator 86 is coupled to a phase matched nonlinear ring resonator 84 (e.g., comb generator) via coupling region 88. As described above, in some embodiments the nonlinear ring resonator is fabricated utilizing nonlinear semiconductor material (e.g., AlGaAs) as described with respect to FIG. 1a, above, and generates in response to the optical input provided by the nonlinear ring resonator 94 a comb of frequencies. The output of the nonlinear ring resonator 84 is coupled to waveguide 82. In some embodiments, additional devices may be coupled to waveguide 82 to operate on the frequency comb generated by nonlinear ring resonator 84.

FIG. 7b is a perspective view illustrating the layout of a comb generator 90, which includes a waveguide 92, nonlinear ring resonator 94, and laser cavity ring resonator 96. In the embodiment shown in FIG. 7b, the nonlinear ring resonator 94 and laser cavity ring resonator 96 are stacked vertically adjacent to one another. In some embodiments, the laser cavity ring resonator 96 is fabricated utilizing quantum wells (QWs) and/or quantum dots (QDs) (e.g., (Al)InGaAs QWs and/or InAs QDs), which generates an optical signal at a first frequency or first plurality of frequencies. The optical signal generated by the laser cavity ring resonator 96 is coupled to a phase matched nonlinear ring resonator 94 (e.g., comb generator) via a coupling region along the entire edge of the respective resonators. As described above, in some embodiments the nonlinear ring resonator is fabricated utilizing nonlinear semiconductor material (e.g., AlGaAs) as described with respect to FIG. 1a, above, and generates in response to the optical input provided by the nonlinear ring resonator 94 a comb of frequencies. The output of nonlinear ring resonator 94 is coupled to waveguide 92. In some embodiments, additional devices may be coupled to waveguide 92 to operate on the frequency comb generated by nonlinear ring resonator 94.

FIG. 7c is a top view illustrating the layout of a comb generator 100, which includes a waveguide 102, nonlinear ring resonator 104, and laser cavity 106. In this embodiment, laser cavity 106 is formed partially surrounding the nonlinear ring resonator. As described above, in some embodiments the laser cavity 106 is fabricated utilizing quantum wells (QWs) and/or quantum dots (QDs) (e.g., (Al)InGaAs QWs and/or InAs QDs), which generates an optical signal at a first frequency or first plurality of frequencies. The optical signal generated by the laser cavity 106 is coupled to a phase matched nonlinear ring resonator 84 (e.g., comb generator) via coupling regions 108 and 110. As described above, in some embodiments the nonlinear ring resonator 104 is fabricated utilizing AlGaAs as described with respect to FIG. 1a, above, and generates in response to the optical input provided by the laser cavity 96 a comb of frequencies. The output of the nonlinear ring resonator 104 is coupled to waveguide 102. In some embodiments, additional devices may be coupled to waveguide 102 to operate on the frequency comb generated by nonlinear ring resonator 104.

One of the benefits of the arrangements illustrated in FIGS. 7a-7c is that the nonlinear ring resonator 104 is not limited by the absorption of the gain material. In addition, in some embodiments the comb generators 80, 90 and 100 shown in FIGS. 7a-7c could be utilized to pump another layer such as a SiO₂ or Si₃N₄ or other dielectric materials, or perhaps GaN (e.g. C³ comb generation).

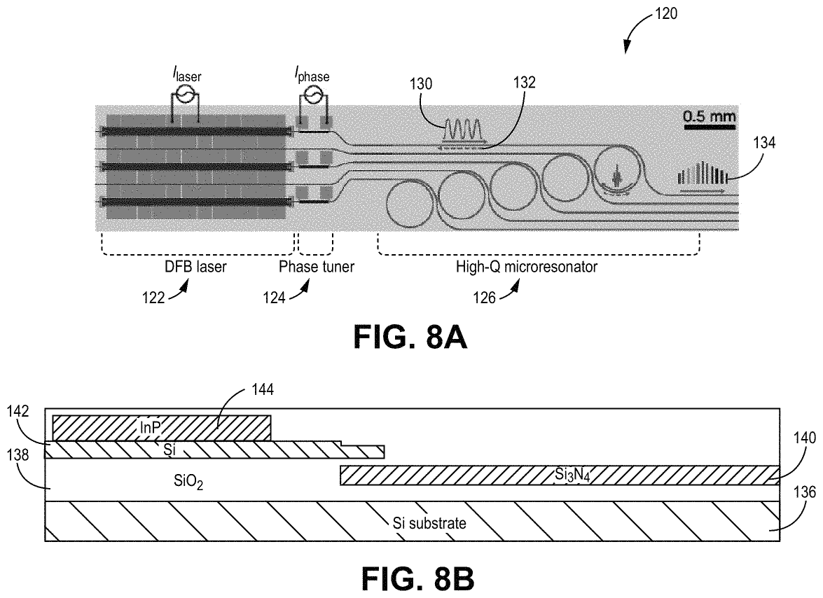

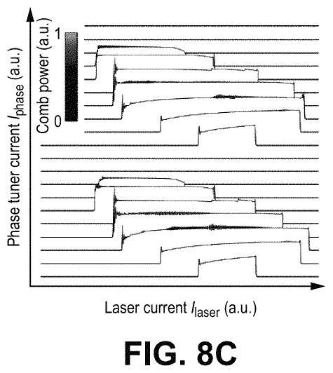

Referring now to FIGS. 8a-8c, a chip-scale laser frequency comb is illustrated according to some embodiments. FIG. 8a is a top view of the chip-scale laser frequency comb; FIG. 8b is a cross-sectional view of the chip-scale laser frequency comb, and FIG. 8c is a graph illustrating microcomb generation with sweeping laser current Iₗₐₛₑᵣ and varying phase tuner current Iₚₕₐₛₑ to control the optical phase of self-injection locking.

The chip-scale laser frequency comb 120 shown in FIG. 8a includes a distributed feedback (DFB) laser 122, a thermo-optic phase tuner 124, and a high-Q nonlinear microresonator 126, combined by leveraging multilayer heterogeneous integration (as shown in FIG. 8b). In some embodiments, the DFB laser 122, phase tuner 124, and nonlinear microresonator 126 are built on InP/Si, Si, and Si3N4 layers, respectively, as discussed in more detail with respect to FIG. 8b.

The DFB laser 122 generates a continuous-wave laser output that is provided to thermo-optic phase tuner 124. In some embodiments, the thermo-optic phase tuner 124 is comprised of a thermo-optic resistive heater that provides optical phase control. The output of the thermo-topic phase tuner 124 is coupled into a high-Q microring resonator 126, wherein Kerr non-linear four-wave mixing generates soliton microcombs. In some embodiments, the high-Q microring resonator 126 is comprised of Si3N4 that exhibits anomalous group velocity dispersion (GVD) in the telecommunication C band and has a free spectral range (FSR) of 100 GHz. In some embodiments, DFB laser 122 directly pumps the microring resonator 126 without an intermediate optical isolator, and the entire device is electronically operated via laser current control and phase control.

In some embodiments, the continuous wave laser output (shown by solid line 130) is coupled into the microresonator 126 and partially backscattered, as illustrated by dashed line 132. The backscattered signal triggers self-injection locking that assists soliton formation inside the microresonator 126. In some embodiments, the locking is optimized by controlling the laser current Iₗₐₛₑᵣ. In some embodiments, laser self-injection locking (11, 12, 13, 14) leverages the narrow-band optical feedback at desired phase relations from a high-Q microresonator 126 to stabilize the pump laser and pulls the laser frequency toward the microring resonance. In this scenario, soliton microcombs can form when optimum laser-microresonator frequency detuning is reached. The DFB laser wavelength increases with increasing laser current, as the grating index increases as a result of injected electrical power heating. Consequently, certain gain currents trigger comb generation when the laser wavelength coincides with a micro-resonator resonance. The comb generation region resides where the laser is red-detuned to the resonance (as shown in FIG. 8c), and the phase of the Rayleigh backscattered light from the microresonator to the laser fulfills certain phase relations.

FIG. 8b is a cross-sectional view of the chip-scale laser frequency comb 120 that illustrates the various layers. In particular, FIG. 8b illustrates the vertical, multilayer structure built on a common substrate 136 (for example, silicon (Si) substrate) realized through sequential wafer bonding of a silicon-on-insulator (SOI) wafer 138 and an InP multiple-quantum-well (InP MQW) epi wafer 144 to a prepatterned Si3N4 substrate 140. In some embodiments, the prepatterned Si3N4 substrate 140 is fabricated using a photonic Damascene process. In some embodiments, the heterogeneous integration is done directly on a 100-mm-diameter Si substrate and processed on the wafer scale.

In some embodiments, fabrication begins with fabrication of the Si3N4 PIC on a Si substrate using a Damascene process with 4-mm-thick thermal wet silicon dioxide (SiO2). The PIC pattern is exposed with deep ultra-violet (DUV) stepper lithography and dry-etched into the SiO2 substrate to form the waveguide preform. Stoichiometric Si3N4 is deposited on the patterned SiO2 preform by using low-pressure chemical vapor deposition (LPCVD), filling the trenches and forming waveguide cores. Chemical-mechanical polishing (CMP) is used to remove excess Si3N4, planarize the wafer front surface, and control the Si3N4 waveguide height (e.g., 780 nm). Afterward, spacer SiO2 of 300-nm thickness is deposited on the Si3N4 substrate. The entire substrate is further annealed (e.g., at 1200° C.) to drive out the residual hydrogen content in Si3N4 and SiO2 and to densify the spacer SiO2. A second CMP is performed to create a flat and smooth wafer surface. In some embodiments, the measured root mean square (RMS) roughness of the wafer surface measured by atomic force microscopy (AFM) is 0.27 nm, enabling direct substrate bonding with an SOI wafer.

In some embodiments, to achieve high bonding yield, vertical channels for outgassing are etched before wafer bonding. Coarse alignment is required to bond blank films on the target areas of the patterned substrate. Fine alignment of patterns on different layers with an accuracy within 100 nm is enabled by DUV stepper lithography. After removing the Si substrate and buried SiO2 layer of the bonded SOI wafer, the Si device layer is processed to create waveguide structures with different etch depths, including shallow-etched Si rib waveguides for the lasers and phase tuners, fully etched hole structures for gratings, and thin Si tapers for mode conversion between the Si waveguide and underlying Si3N4 waveguide. In some embodiments, InP-based MQW gain material is then bonded to the patterned Si device at the active regions. In some embodiments, the InP process starts with InP substrate removal, which may include InP mesa etches. In some embodiments, P-type InP, InAlGaAs MQW, and N-type InP etching are performed by selective dry etching and wet etching. P- and N-type contact metals are deposited on the P—InGaAs layer and N—InP layer, respectively. In some embodiments, the excess Si on top of Si3N4 microresonators is removed before laser passivation by hydrogen-free deuterated SiO2 deposition (27). Vias are then etched for laser electrical contact, followed by proton implantation on the laser mesa structure to reduce electrical current leakage. In some embodiments, heater and probe metals are deposited at the end of the full process and the entire wafer is then diced into dozens of dies or chips to facilitate testing. In some embodiments, the InP/Si-to-Si rib waveguide transition loss is below 1 dB, and the Si-to-Si3N4 mode conversion efficiency is simulated to be above 90%. Assuming all devices share the same design, the overall device yield is determined primarily by the SOI bonding and InP bonding yields. In the current wafer, we have achieved bonding yields that enable thousands of complete laser-microresonator devices, each of which has a footprint as small as 1.6 mm2.

In some embodiments, an integrated laser/resonator includes a semiconductor/dielectric substrate, a pump laser fabricated on the substrate, and a microresonator fabricated on the same substrate, wherein the microresonator is coupled to the pump laser. In some embodiments, The integrated laser/resonator of claim 17, wherein the non-linear layer is comprised of GaAs, GaN, InSb, InAs, InₓGa₁₋ₓN, AlₓGa₁₋ₓAs, InₓGa₁₋ₓAs_{1-y}P_{1-y}, InₓGa₁₋ₓAs_{1-y}Sb_{1-y}, InₓGa₁₋ₓSb_{1-y}P_{1-y}, InₓGa_{y}Al_{1-x-y}As, InₓGa_{y}Al_{1-x-y}N where 0<x<1, 0<y<1, dielectric materials such as silicon nitride, silica, Ta₂O₅, LiNbO₃, diamond Hydex, and MgF₂.

Although the embodiments described above were provided with respect to frequency comb generation, the nonlinear effects described may be utilized in other devices such as Second Harmonic Generation (SHG) devices, Optical Parametric Oscillation (OPO) devices, Stimulated Brillouin Scattering (SBS) devices, and Raman Scattering devices.

1. An integrated laser/non-linear device comprising:
a semiconductor/dielectric substrate;
a nonlinear device fabricated on the semiconductor/dielectric substrate; and
a pump laser fabricated on the same semiconductor/dielectric substrate.

2. The integrated laser/non-linear device of claim 1, wherein the nonlinear device is a resonator.

3. The integrated laser/non-linear device of claim 1, wherein the nonlinear device is a waveguide.

4. The integrated laser/nonlinear device of claim 1, wherein the nonlinear device includes one or more of a frequency comb generator, stimulated Brillouin effect, Raman effect, second harmonic generator, and/or optical parametric oscillator.

5. The integrated laser/nonlinear device of claim 1, wherein the nonlinear device comprises one or more of GaAs, GaN, InSb, InAs, InₓGa₁₋ₓN, AlₓGa₁₋ₓAs, InₓGa₁₋ₓAs_{1-y}P_{1-y}, InₓGa₁₋ₓAs_{1-y}Sb_{1-y}, InₓGa₁₋ₓSb_{1-y}P_{1-y}, InₓGa_{y}Al_{1-x-y}As, InₓGa_{y}Al_{1-x-y}N where 0<x<1, 0<y<1.

6. The integrated laser/nonlinear device of claim 5, wherein the nonlinear device comprises one or more of silicon nitride, silica, Si, Ta₂O₅, LiNbO₃, SiC, diamond, Hydex, and MgF₂.

7. The integrated laser/nonlinear device of claim 1, wherein the nonlinear device is a frequency comb generator, a stimulated Brillouin laser, a Raman laser, a second harmonic generator, and/or an optical parametric oscillator.

8. An integrated non-linear laser comprising:
a waveguide; and
a resonator laser coupled to the waveguide via a coupler, wherein at least a portion of the resonator laser includes a gain section and at least a portion of the resonator laser comprises a non-linear waveguide.

9. The integrated non-linear laser of claim 8, wherein the nonlinear waveguide is comprised of semiconductor and/or dielectric waveguide.

10. The integrated non-linear laser of claim 9, wherein the nonlinear waveguide comprises one or more of GaAs, GaN, InSb, InAs, InₓGa₁₋ₓN, AlₓGa₁₋ₓAs, InₓGa₁₋ₓAs_{1-y}P_{1-y}, InₓGa₁₋ₓAs_{1-y}Sb_{1-y}, InₓGa₁₋ₓSb_{1-y}P_{1-y}, InₓGa_{y}Al_{1-x-y}As, and InₓGa_{y}Al_{1-x-y}N where 0<x<1, 0<y<1, or dielectric materials such as silicon nitride, silica, Si, Ta₂O₅, LiNbO₃, SiC, diamond, Hydex, and MgF₂.

11. A frequency comb generator comprising:
a resonator laser;
a nonlinear resonator ring coupled to the resonator laser to receive an input optical signal at a first frequency or first plurality of frequencies and to generate in response a frequency comb output; and
a waveguide coupled via a coupler to the nonlinear resonator to receive the frequency comb optical output in response to the first frequency of first plurality of frequencies of the input optical signal.

12. The frequency comb generator of claim 11, wherein the nonlinear resonator ring is comprised of a semiconductor and/or a dielectric waveguide.

13. The frequency comb generator of claim 12, wherein the nonlinear resonator ring comprises one or more of nonlinear waveguide comprises one or more of GaAs, GaN, InSb, InAs, InₓGa₁₋ₓN, AlₓGa₁₋ₓAs, InₓGa₁₋ₓAs_{1-y}P_{1-y}, InₓGa₁₋ₓAs_{1-y}Sb_{1-y}, InₓGa₁₋ₓSb_{1-y}P_{1-y}, InₓGa_{y}Al_{1-x-y}As, and InₓGa_{y}Al_{1-x-y}N where 0<x<1, 0<y<1, or dielectric materials such as silicon nitride, silica, Si, Ta₂O₅, LiNbO₃, SiC, diamond, Hydex, and MgF₂.

14. The frequency comb generator of claim 11, wherein the resonator laser is laterally coupled to the non-linear resonator ring.

15. The frequency comb generator of claim 11, wherein the resonator laser is vertically coupled to the nonlinear resonator ring.

16. A frequency comb generator comprising:
a gain waveguide;
a non-linear resonator coupled to the gain waveguide to receive an input optical signal at a first frequency or first plurality of frequencies and to generate in response a frequency comb output; and
a waveguide coupled via a coupler to the non-linear resonator to receive the frequency comb optical output in response to the first frequency of first plurality of frequencies of the input optical signal.
